(19) United States
(12) Patent Application Publication
(10) Pub. No.: US 2012/0092820 A1
(43) Pub. Date: Apr. 19, 2012

(54) PORTABLE ELECTRONIC DEVICE WITH SLIDE AND TILT MECHANISM

(75) Inventors: Mika Antero Hautamaki, Vesilahti (FI); Pasi Tuomo Antero Kemppinen, Tampere (FI)

(73) Assignee: NOKIA CORPORATION, Espoo (FI)

(21) Appl. No.: 13/140,936

(22) PCT Filed: Dec. 19, 2008
(86) PCT No.: PCT/EP2008/010969

§ 371 Date: Nov. 7, 2011

(51) Int. Cl. G06F 1/16; H05K 5/03; B23P 11/00; H05K 5/00

(52) U.S. Cl. 361/679.02; 361/679.01; 312/107; 29/434

(57) ABSTRACT

An apparatus (100) for a portable electronic device, the apparatus comprising first and second housings (1, 2) and a shield member (3), the first and second housings (1, 2) configured to be laterally slidable relative to one another between a first configuration and a second configuration, the second configuration providing a configuration in which the second housing (2) is moved laterally away from the first housing (1) compared to the first configuration, wherein the apparatus (100) is configured to be moveable from the second configuration to a third configuration in which the second housing (2) is tilted relative to the first housing (1) to reveal a defined spacing (S) between the tilted first and second housings (1, 2), and wherein the apparatus (100) is configured such that the shield member (3) is positioned to at least partially enclose the spacing (S) defined between the tilted first and second housings (1, 2) in the third configuration.

### TECHNICAL FIELD

The present disclosure relates to the field of portable electronic devices, for example portable electronic devices with slide and tilt mechanisms, together with associated methods, computer programs and apparatus. Certain disclosed aspects/embodiments relate to portable electronic devices, in particular, so-called hand-portable electronic devices which may be hand-held in use (although they may be placed in a cradle in use). Such hand-portable electronic devices include so-called Personal Digital Assistants (PDAs).

The portable electronic devices/apparatus according to one or more disclosed aspects/embodiments may provide one or more audio/text/video communication functions (for example tele-communication, video-communication, and/or text transmission (Short Message Service (SMS)/Multimedia Message Service (MMS)/emailing) functions), interactive/non-interactive viewing functions (for example web-browsing, navigation, TV/program viewing functions), music recording/playing functions (for example MP3 or other format and/or (FM/AM) radio broadcast recording/playing), downloading/sending of data functions, image capture function (for example using a (for example in-built) digital camera), and gaming functions.

### BACKGROUND

It is desirable for certain devices (typically portable electronic devices, for example, mobile phones, laptops, etc.) to be arranged so that they can adopt more than one form factor. This enables devices to adopt numerous configurations, in that they can take on one configuration that is suitable/optimised for one type of use, and are also movable into further configurations that are suitable/optimised for different types of use.

FIG. 1 shows an example of such a device. This device uses what is known as a ‘slide-and-tilt’ mechanism, or slide-tilt mechanism, that is, the device is configured to ‘slide’ from a first configuration to a second configuration, and to ‘tilt’ from this second configuration to a third configuration. This allows a user to use the device in three different configurations for various functionalities. The device shown in FIG. 1 is in the third configuration.

As can be seen in FIG. 1, the ‘tilt’ mechanism is completely exposed in the third configuration. The spacing shown in FIG. 1 is defined between the lower surface of the upper housing, and the upper surface of the lower housing. The lower housing can be considered to be a first housing, and the upper housing can be considered to be a second housing. The spacing is revealed by the tilting of the second housing relative to the first housing. This tilting action can be considered to reveal or create/define a substantially wedge shaped spacing or cavity between the first and second housings. The exposure of the mechanism is typical when the devices are in this tilted state. This presents many issues that can affect the device and hinder the performance of devices employing such a mechanism.

The listing or discussion of a prior-published document or any background in this specification should not necessarily be taken as an acknowledgement that the document or background is part of the state of the art or is common general knowledge. One or more aspects/embodiments of the present disclosure may or may not address one or more of the background issues.

### SUMMARY

In a first aspect, there is provided an apparatus for a portable electronic device, the apparatus comprising first and second housings and a shield member, the first and second housings configured to be laterally slidable relative to one another between a first configuration and a second configuration, the second configuration providing a configuration in which the second housing is moved laterally away from the first housing compared to the first configuration, wherein the apparatus is configured to be moveable from the second configuration to a third configuration in which the second housing is tilted relative to the first housing to reveal a defined spacing between the tilted first and second housings, and wherein the apparatus is configured such that the shield member is positioned to at least partially enclose the spacing defined between the tilted first and second housings in the third configuration.

The apparatus may, or may not, be for a portable electronic device.

The apparatus can use the shielding mechanism to protect any mechanisms/moving parts that may be located in the defined spacing. The shield mechanism covers said spacing when the apparatus is in the third configuration, thus reducing the risk of dust and impurities entering into the device or getting between the lower first housing and upper second housing.

This can provide benefits, as these issues can diminish the useable life of apparatus such as portable electronic devices, as the dust and impurities can degrade, damage or destroy components within the device, or even the housing or the slide-tilt mechanism. The tilting action creates what is, in the prior art, an undesirable spacing (see FIG. 1) which apparatus disclosed herein can at least partially enclose. This can protect any inner components/mechanisms of the device.

By providing the apparatus with a shield member in the manner described above, it is possible to cover this undesirable spacing. This shields and protects the mechanism and inner components/mechanisms of the apparatus from unwanted material entering into or damaging the mechanism/apparatus, and encloses this previously undesirable spacing to achieve an enclosed or partially enclosed volume.

Furthermore, the mechanism responsible for providing the sliding and tilting motions is no longer completely exposed in this tilted state. The mechanism can be unattractive for the user to have to see this portion of the device, as it can disrupt the overall appearance of the device.

The apparatus may be configured to be laterally moveable in the same plane from the first configuration to the second configuration.

The apparatus may be configured to be moveable from the second configuration to the third configuration about a pivot point such that the relative lateral position of the first and second housing is substantially the same in the second and third configurations.

The apparatus may be configured to move the shield member from a non-shielding position when the apparatus is in the first and second configurations, to a shielding position when the apparatus is in the third configuration.

The apparatus may be configured to position the shield member to lie adjacent to an exterior face of the second housing in the non-shielding position, and to move the shield member to the shielding position with the movement from the second configuration to the third configuration.

The shield member may be slidably attached to the second housing to allow the shield member to maintain its position with respect to the first and second housings in the first and second configurations but move with the second housing to the shielding position with movement from the second to the third configuration.

For example, the second housing may be capable of sliding past the shield member until it reaches its maximum sliding displacement to provide the second configuration, and then to move with the shield member when it is tilted relative to the first housing to provide the third configuration. In this way, the shield member can be positioned into the shielding position when the device is in the third configuration.

The shield member may comprise a non-flexible material.

The apparatus may be configured to house the shield member between the first and second housings in the non-shielding position, and to bias the shield member out from between the first and second housings to the shielding position with movement from the second configuration to the third configuration.

The apparatus may be configured to foldably house the shield member between the first and second housings in the non-shielding position and to unfold the shield member to provide the shielding position.

The shield member may comprise a resilient material to unfold the shield member with movement from the second configuration to the third configuration to provide the shielding position.

The shield member may comprise a concertina, the shield member being compressed in the non-shielding position compared to the shielding position.

The apparatus may be configured such that the shield member covers an input/output port and/or camera lens of the device in the non-shielding position.

The apparatus may be configured such that the shield member is provided along a major face of the defined spacing to substantially cover that major face.

The spacing defined between the first and second housings may be considered to be an imaginary three-dimensional geometric shape that has two of its faces bounded by the first and second housings. In some embodiments, the geometric shape may be a wedge shaped prism. The prism may have five faces, three side faces and two end faces, wherein the side faces are larger than the two end faces. These three side faces can be considered to be major faces of the spacing, whilst the two smaller end faces can be considered to be minor faces of the spacing. Two of the three major faces are bounded by the first and second housings, whilst the third major face is an imaginary face that is not bounded by any physical surface. In some embodiments, it is this issue of covering this open defined spacing that the invention is addressing, and in particular, covering the open side face that is not bound by a housing.

The shield member may be configured to completely enclose the defined spacing when in the third configuration.

The shield member may be configured to wrap around from a major face of the defined spacing to an adjacent/end face of the defined spacing in the shielding position, This may substantially cover at least two adjacent/end faces of said spacing.

The shield member may comprise a plurality of members to enclose the spacing defined between the tilted first and second housings in the third configuration.

The plurality of members may be provided for respective faces of the spacing defined between the tilted first and second housings in the third configuration.

The first and second housings may be moved laterally in planes parallel to one another between the first and second configuration.

The apparatus may be configured to be mechanically biased to move between at least two of the first, second and third configurations.

The mechanical biasing may be provided by a motor or motorised bias.

The motor(ised) bias, for example, may be configured to apply a force to the second housing to move it between at least two of the first, second and third configurations, and in some embodiments move the second housing from the second to the third configuration.

The shield member may comprise a flexible curtain, and the apparatus may be configured to unfurl/unroll the shield member with movement from the second configuration to the third configuration to provide the shielding position.

According to a second aspect, there is provided a portable electronic device comprising an apparatus for a portable electronic device, the apparatus comprising first and second housings and a shield member, the first and second housings configured to be laterally slidable relative to one another between a first configuration and a second configuration, the second configuration providing a configuration in which the second housing is moved laterally away from the first housing compared to the first configuration, wherein the apparatus is configured to be moveable from the second configuration to a third configuration in which the second housing is tilted relative to the first housing to reveal a defined spacing between the tilted first and second housings, and wherein the apparatus is configured such that the shield member is positioned to at least partially enclose the spacing defined between the tilted first and second housings in the third configuration.

According to a third aspect, there is provided a computer program, recorded on a recording medium, for configuring an apparatus for a portable electronic device, the apparatus comprising first and second housings and a shield member, the first and second housings configured to be laterally slidable relative to one another between a first configuration and a second configuration, the second configuration providing a configuration in which the second housing is moved laterally away from the first housing compared to the first configuration, wherein the apparatus is configured to be moveable from the second configuration to a third configuration in which the second housing is tilted relative to the first housing to reveal a defined spacing between the tilted first and second housings, and wherein the apparatus is configured such that the shield member is positioned to at least partially enclose the spacing defined between the tilted first and second housings in the third configuration.

The computer program may comprise computer code to detect the configuration of the apparatus, and move the shield member into position based on the detected configuration.

According to a fourth aspect, there is provided a method of assembling an apparatus for a portable electronic device, the apparatus comprising first and second housings and a shield member, the first and second housings configured to be laterally slidable relative to one another between a first configuration and a second configuration, the second configuration providing a configuration in which the second housing is moved laterally away from the first housing compared to the first configuration, wherein the apparatus is configured to be moveable from the second configuration to a third configuration in which the second housing is tilted relative to the first housing to reveal a defined spacing between the tilted first and second housings, and wherein the apparatus is configured such that the shield member is positioned to at least partially enclose the spacing defined between the tilted first and second housings in the third configuration, the method comprising assembling the first and second housings and shield member for movement between the first, second and third configurations.

According to a fifth aspect, there is provided an apparatus for an electronic device, the apparatus comprising first and second means for housing and a means for shielding, the first and second means for housings configured to be laterally slidable relative to one another between a first configuration and a second configuration, the second configuration providing a configuration in which the second means for housing is moved laterally away from the first means for housing compared to the first configuration, wherein the apparatus is configured to be moveable from the second configuration to a third configuration in which the second means for housing is tilted relative to the first means for housing to reveal a defined spacing between the tilted first and second means for housings, and wherein the means for shielding is configured to be positioned to at least partially enclose the spacing defined between the tilted first and second means for housing in the third configuration.

The present disclosure includes one or more corresponding aspects, embodiments or features in isolation or in various combinations whether or not specifically stated (including claimed) in that combination or in isolation. Corresponding means for performing one or more of the discussed functions are also within the present disclosure.

The above summary is intended to be merely exemplary and non-limiting.

### BRIEF DESCRIPTION OF THE FIGURES

A description is now given, by way of example only, with reference to the accompanying drawings, in which: —

FIG. 1 shows an example of a ‘slide-and-tilt mechanism’.

FIG. 2 illustrates first and second housings.

FIGS. 3a-c show first, second and third configurations of an apparatus according to a first embodiment.

FIGS. 4a-c show first, second and third configurations of an apparatus according to a second embodiment.

FIGS. 5a-c show first, second and third configurations of an apparatus according to a third embodiment.

FIGS. 6a-c show first, second and third configurations of an apparatus according to a fourth embodiment.

FIG. 7 shows rails and complementary grooves arrangement of a slide and tilt mechanism.

FIG. 8 shows further implementation details of a shield member connected to a sliding mechanism.

FIG. 9 shows calculations of maximum opening angle so that a given shield member overlies a first housing when in the tilted state.

### DESCRIPTION OF SPECIFIC ASPECTS/EMBODIMENTS

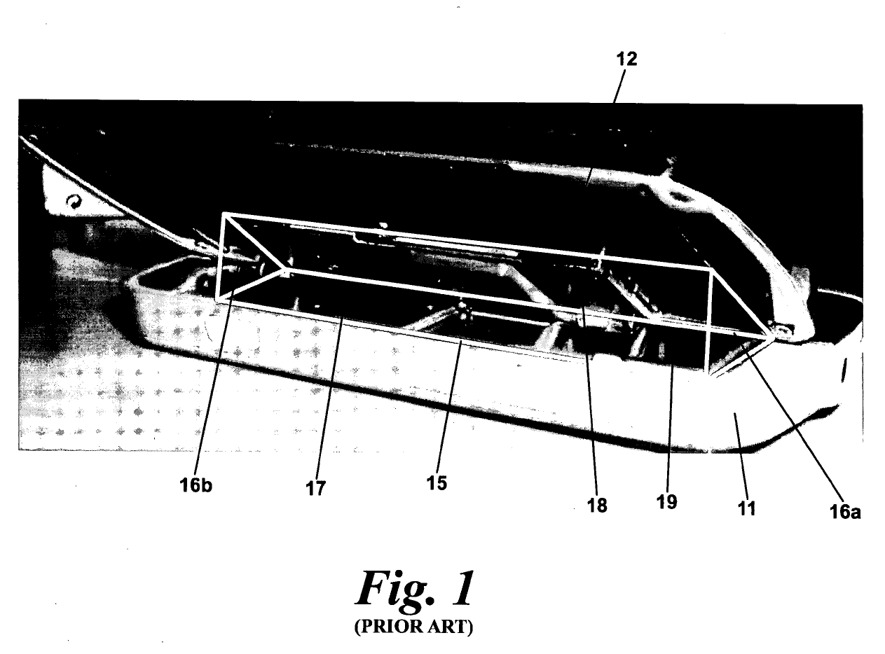

The present invention is directed towards providing a shield member for an apparatus having a slide-tilt mechanism, that allows for at least partial enclosure of a spacing defined between a first lower housing and a second upper housing of the device (the spacing 15 is shown in FIG. 1).

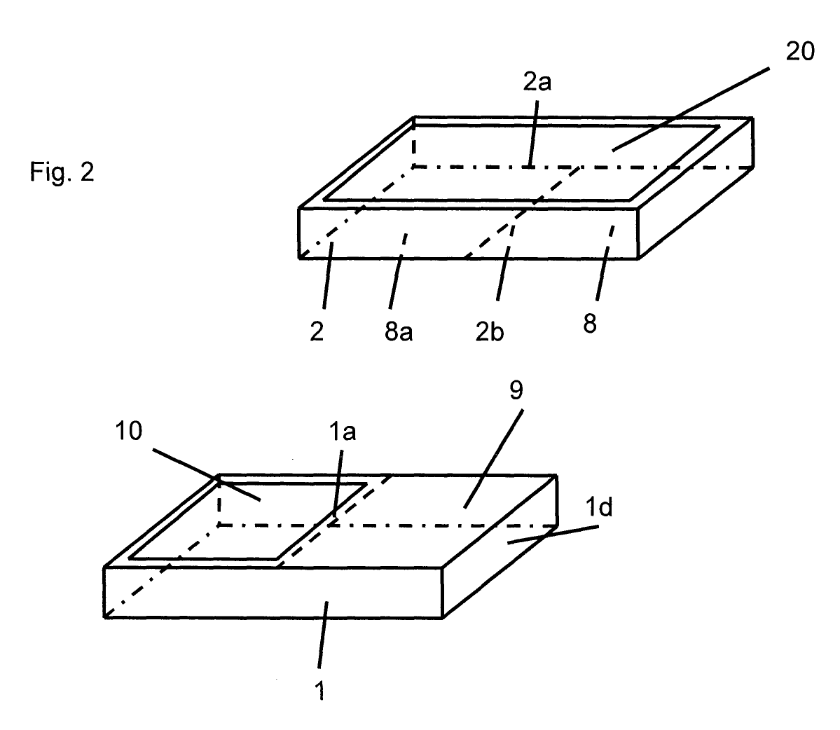

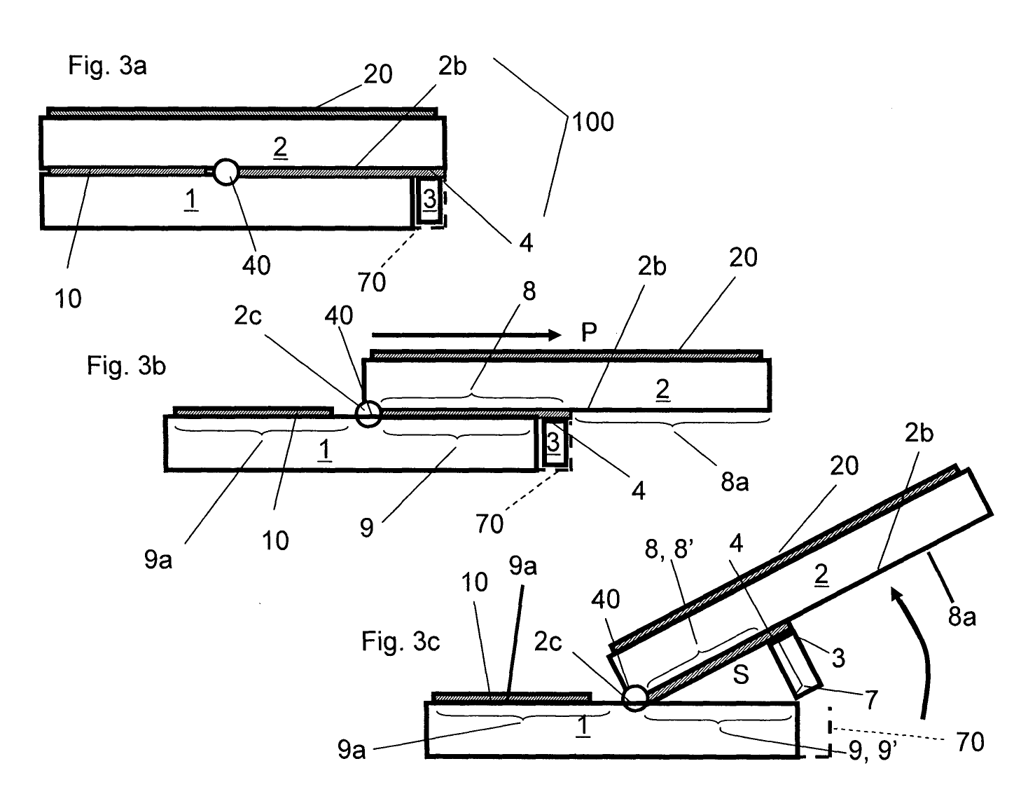

FIGS. 3a-3c show a side view of an apparatus 100 according to a first embodiment. The apparatus comprises a first housing 1, a second housing 2, and a shield member 3. Perspective views of the first and second housings 1, 2 are illustrated in FIG. 2.

The first housing 1 comprises an input area 10 arranged on a first face 1a of the first housing 1, which in use can be considered to be a top face la of the first housing 1. The first input area is a keypad that allows for user input. It will be apparent to the skilled person that at least one of various different types of input area can be used, for example a touch pad, track ball, touch sensitive display etc, as well as, or in place of the keypad. The first housing also comprises a right face 1d.

The second housing comprises an input/output area 20 arranged on a first face 2a of the second housing 2. In use, the first face can be considered to be a top face 2a. The input/output area 20 comprises a touch sensitive display 21 to allow for user input and to provide user output. The second housing 2 also comprises a second face 2b, which in use can be considered to be a bottom face 2b of the second housing 2.

It will be appreciated that the input area 10 is shown raised above the first housing 1 for illustrative purposes, and that in some embodiments the input area 10 may be flush with the first housing 1. This is also the case with input/output area 20.

As shown in FIG. 3a, the apparatus 100 is configured to have a first configuration in which the second housing 2 overlies the first housing 1. The first face of the first housing 1a, which includes the input area 10, is completely covered by the second housing 2 in this first configuration, in that the top face la of the first housing 1 is adjacent and parallel to the bottom face 2b of the second housing 2. The top face 2a of the second housing 2 is fully exposed in this configuration as it provides the uppermost face of the apparatus 100.

This first configuration provides a substantially mono-block form factor, for example, for typical phone use of making and receiving voice calls.

As shown in FIG. 3b, the apparatus 100 is also configured to have a second configuration in which the second housing 2 is laterally offset relative to the first housing, in that the second housing 2 can be moved laterally away from the first housing 1, but where the second housing 2 still overlies a portion of the first face 1a of the first housing 1 (as seen in FIG. 3b). The input area 10 provided on the first housing 1 is exposed in this second configuration.

The top face 1a of the first housing 1 can be considered as having two portions: an exposed portion 9a that is exposed in the second configuration, and a covered portion 9 that is substantially covered by the second housing 2 in the second configuration. The input area 10 is provided on the exposed portion 9a.

The bottom face 2b of the second housing 2 can be defined as having two portions: an exposed portion 8a that is exposed in the second configuration, and a covered portion 8 that is substantially covered in the second configuration.

The covered portion 9 of the first housing 1 and the covered portion 8 of the second housing 2 are adjacent and parallel to each other when the apparatus 100 is in the second configuration.

This second configuration provides a form factor suitable for entering data into input area 10 and viewing displayed information on the apparatus 100 via input/output area 20.

As shown in FIG. 3c, the apparatus 100 is further configured to have a third configuration in which the second housing 2 is tilted relative to the first housing 1. This tilted configuration reveals/creates a defined spacing S between the tilted second housing 2, and the first housing 1.

Upon movement of the apparatus 100 from the second configuration to the third configuration, the covered portion 9 of the first housing 1 and the covered portion 8 of the second housing 2 are moved to be tilted with respect to one another, in that they are no longer adjacent or parallel to each other and a tilting angle is defined between them.

This spacing is the open volume defined by the covered portion 9 of the top face 1a of the first housing 1, and by the covered portion 8 of the bottom face 2b of the second housing 2.

This third configuration provides a third form factor suitable for entering data, and provides for a convenient tilting of the input/output area 20 for the user. The form factor of the third configuration can provide for more ergonomic use and allows for ease of viewing and data entry.

The first and second housings 1, 2 are configured to be laterally slidable relative to each other between the first and second configurations.

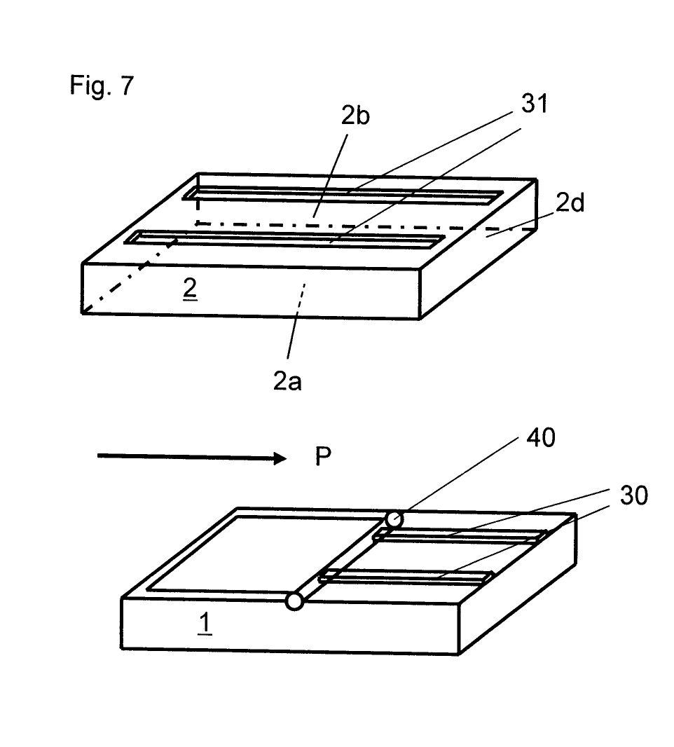

FIG. 7 shows an arrangement by which this lateral sliding motion can be achieved. The sliding motion is provided by rails 30 provided on portion 9 of the top face la of the first housing 1, and by complementary grooves 31 provided on the bottom face 2b of the second housing 2. The second housing 2 is depicted upside down in FIG. 7 so as to clearly illustrate the grooves 31.

The rails 30 and grooves 31 can be mated to allow the first and second housings 1, 2 to be laterally slidable in a longitudinal axis of the housings (in that they are relatively slidable along sliding axis P), and thereby allows the apparatus 100 to be slidably movable between the first configuration and the second configuration. It will be appreciated that the first and second housing can be laterally moveable in a longitudinal direction along a length of the device, or in a direction across the width of the device.

As shown in FIGS. 3b and 3c, the second housing 2 is configured to be tiltable (relative to the first housing 1) to move the apparatus between the second and third configurations. The tilting motion is provided by a pivot 40 provided on the apparatus 100. The pivot 40 rotatably connects the first and second housings 1, 2.

With respect to the first housing 1, the pivot 40 is fixedly connected to the first housing 1 on the top face la between the exposed portion 9a and the covered portion 9 on the top face la of the first housing.

The second housing 2 is slidably connected to the pivot 40 such that the second housing 2 moves relative to both the first housing 1, and the pivot 40 during the lateral sliding movement to change from the first configuration to the second configuration until the second housing 2 reaches the end of its travel path, as defined by the rail/groove sliding arrangement.

In the second configuration, the pivot 40 is located at the left edge 2c of the bottom face 2b (relative to sliding axis P) of the second housing 2. This allows the second housing 2 to be tiltable about this pivot point, thereby allowing the apparatus 100 to move from the second configuration to the third configuration. This also allows the relative lateral position of the first and second housings 1, 2 to remain substantially the same in the second and third configurations, in that there is no substantial lateral movement of the second housing 2 relative to the first housing 1 during the tilting motion.

It will be appreciated by the skilled person that the pivot 40 can be provided in a reverse arrangement, by which it is fixedly attached to the leftmost edge 2c of the bottom face 2b of the second housing 2, and slidably connected to the top face la of the first housing 1.

The shield member 3, as illustrated in FIGS. 3a-c, is positioned to provide a non-shielding position in the first and second configurations, and to provide a shielding position in the third configuration.

The shield member 3 is connected to the pivot 40 by backplate 4, and is configured to be slidably connected to the second housing 2 via the sliding arrangement of the rails 30/complementary grooves 31 (shown in further detail in FIG. 7).

In the non-shielding position (FIGS. 3a and 3b), the shield member 3 is configured to be positioned adjacent to the right face 1d of the first housing 1. When the apparatus 100 moves from the first configuration to the second configuration, the shield member 3 remains adjacent to the right face 1d.

In the shielding position (FIG. 3c), the shield member 3 is configured to be positioned so as to partially enclose the defined spacing S between the tilted first and second housings. In this particular embodiment, as shown in FIG. 3c, the shield member 3 is configured to be positioned to cover a major face of the defined spacing S.

The spacing S is, in this embodiment, an imaginary volume in the shape of a wedge shaped prism. It is defined between covered portion 8 of the second housing 2 and the covered portion 9 of the first housing 1.

Shown in FIG. 1 is a spacing defined by first and second housings 11, 12, which define a wedge shaped spacing defined by five imaginary faces, three of which are major 17, 18, 19, and two of which are minor 16a & 16b. The major faces may be considered as side faces and the minor faces may be considered as end faces. The defining of this spacing in the present embodiment is discussed in more detail below, together with how it is enclosed/partially enclosed by the shield member 3.

As discussed above, the prism has five faces. FIG. 3c illustrates, in a profile view, the defined spacing in relation to the present embodiment. Three of the faces of the substantially prismic spacing are larger than the remaining two faces 7, 8′ & 9′. These three faces 7, 8′ & 9′ can be considered to be major faces of the spacing, whilst the two smaller faces can be considered to be minor faces of the spacing. The covered portions 8 & 9 of the first and second housings 1 & 2 are physical surfaces that define and are adjacent to two of these major faces 8′, 9′ of the spacing. The third major face 7 is an imaginary face that is not bounded by any physical surface. In this embodiment, it is this face that the shield member 3 is positioned to be adjacent to and to cover. The two minor faces can be considered to be the two ends of this imaginary prism. These are in two respective planes that are perpendicular to the planes occupied by the major faces 7, 8′, 9′.

In this embodiment the backplate 4 is a flat plate that connects the shield member 3 to the pivot 40. However, it will be appreciated by the skilled person that other connective means are within the scope of this disclosure. For example, arms that extend around the exterior faces of the first housing 1 to connect the outer edges of the shield member 3 to the pivot 40 may be used, or a separate mechanism altogether could be used. The skilled person will therefore appreciate that any physical means by which the shield member 3 can be configured to remain in the same position relative to the first housing 1 in the first and second configurations, and to move with the second housing 2 upon movement of the apparatus 100 into the third configuration, is within the scope of the invention.

As shown in FIGS. 3a and 3b, as the apparatus 100 moves from the first configuration to the second configuration, the shield member 3 does not move or slide relative to the first housing 1. The shield member 3 remains stationary relative to the first housing 1 during movement from the first to second configuration.

The slidable connection between the shield member 3 and the second housing 2 allows the shield member 3 to remain adjacent to the right face 1d of the first housing in the first and second configurations, and not to move with the second housing 2 during the lateral sliding movement.

As shown in FIGS. 3b to 3c, as the second housing 2 moves into its tilted state (see FIG. 3c), the shield member 3 is configured to move with the second housing 2. The slidable connection between the shield member 3 and the second housing 2 only permits sliding action between these two components. As they are both connected via this slidable connection, together with the pivot 40 the shield member 3 is able to move with the second housing 2 with movement from the second configuration to the third configuration. This tilting action moves the shield member 3 into the shielding position, in which it is configured to at least partially enclose the defined spacing S in the shielding position.

In further embodiments, the shield member 3 completely encloses the defined spacing S. That is, the shield member 3 can totally surround the spacing revealed/created between the tilted first and second housings 1, 2. This spacing may also be referred to as a volume or cavity.

The shield member 3 in such embodiments is comprised of a plurality of shield members. Each of these shield members covers a respective imaginary face of the defined spacing to fully encapsulate said spacing, in that they cover and are adjacent to major face 7 and the two minor/end faces to completely enclose the spacing S defined by these faces. This full encapsulation of the spacing may be considered equivalent to a total enclosure of said spacing.

In another of these embodiments, the shield member 3 is configured to wrap around from a major face of the defined spacing to at least one adjacent minor face (for example, configured to wrap around from surface 17 to surface 16a and/or 16b of the spacing as shown in FIG. 1) so as to cover one or both of these faces. This can also cover the corners of the first housing 1.

Completely enclosing the defined spacing ensures that there is reduced exposure of the defined spacing, and therefore no exposure of the slide and tilt mechanism. By enclosing the spacing in this way, the mechanism and inner components/mechanisms of the device experience greater protection from the abovementioned issues of dust, water, impurities, etc. It also helps reduce/minimise the risk of fingers getting caught in the spacing when the apparatus moves into the second configuration from the third configuration.

In another of these embodiments, the apparatus 100 is provided with a wall member 70 that covers the shield member 3 when it is in the non-shielding position. Wall member 70 is shown in dashed lines in FIGS. 3a-c and is an optional feature of some embodiments described herein. The shield member 3 is located between this wall member 70 and the right face 1d of the first housing 1 in the non-shielding position. The shield member 3 moves out of this location upon movement to the shielding position.

Any apparatus described herein can be provided in, or as a portable electronic device, such as a mobile phone, laptop, PDA, pager, hand-held console etc. The shielding action of the shield member can also be provided separately to existing devices that use slide-tilt mechanisms, in that it can be provided as a separate shielding mechanism/component/module that may be retro-fitted to a device.

Returning to FIG. 3, the tilting movement also causes the shield member 3 to move from its non-shielding position adjacent to the right face 1d of the first housing 1, thereby exposing said right face 1d.

In a further embodiment, the right face 1d of the first housing is provided with a peripheral input/output (I/O) area, which may comprise, for example, USB plug, charger socket, camera lens, IR port, memory card slot/card readers, etc. This area is covered by the shield member 3 when the shield member 3 is in the non-shielding position, and is exposed when the shield member 3 is in the shielding position. This allows ports, interfaces, card readers, utilities etc, to be covered and protected when the shield member 3 is in the non-shielding position, and to be revealed and ready for use when the shield member 3 is in the shielding position.

In this embodiment, the shield member 3 is formed from non-flexible sheet metal to provide a solid/substantial/non-flexible shield to enclose the spacing. However, it will be appreciated by the skilled person that numerous other materials can be used. For example, metals such as stainless steel, aluminium, etc could be used. Also, various types of plastic such as acrylonitrile butadiene styrene (ABS), polyvinyl chloride (PVC), etc could be used.

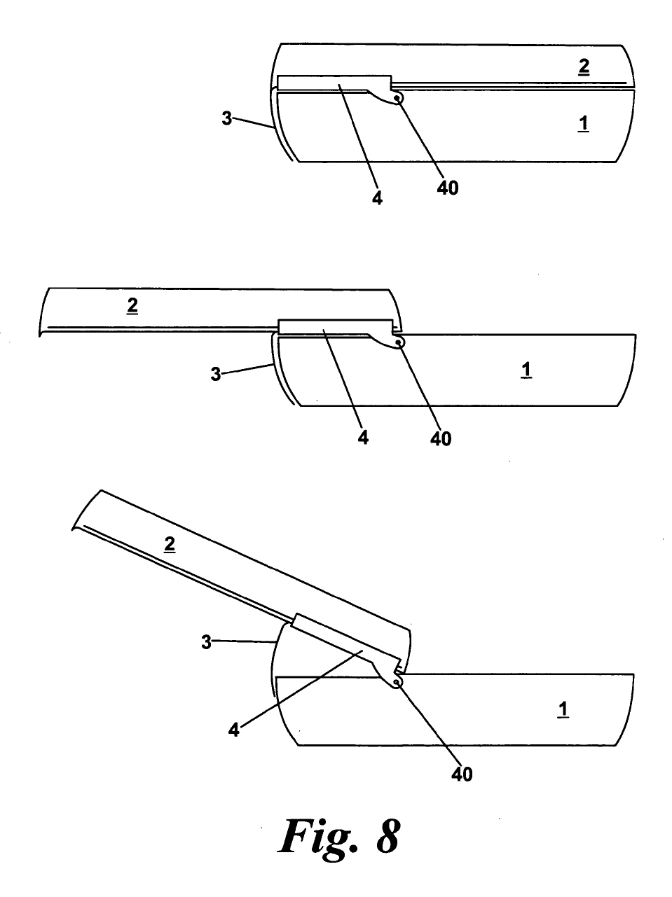

FIG. 8 illustrates another embodiment. In this figure, a shield member 3 can be seen to be connected to a pivot 40 by backplate 4. The backplate 4 is connected to the sliding mechanism provided by the rails and the complementary grooves (as shown in FIG. 7) so as to allow it to remain stationary relative to the first housing 1 during lateral sliding of the second housing 2.

In this embodiment, the rails are provided on the backplate 4. This allows the second housing 2 to laterally slide relative to the first housing 1 and the shield member 3. Once the second housing 2 reaches the end of its defined sliding travel path (determined by the grooves) to place the apparatus in the second configuration, the second housing 2 together with the shield member 3 and backplate 4 can be tilted relative to the first housing 1 to move the apparatus from the second configuration to the third configuration.

As already discussed, this slide-tilt arrangement and also the connection of the shielding arrangement can be reversed. For example, the rails can instead be provided on second housing 2 and the complementary grooves provided on the backplate 4.

As the backplate 4 can simply connect to a pre-existing slide arrangement of a slide-tilt mechanism, this shielding of the defined space can be easy to implement. No extra complicated mechanisms are needed to provide this shielding.

As also shown in FIG. 8, the shield member 3 is substantially curved to follow the shape of the right face 1d of the first housing. This provides a substantially smooth and continuous surface formed by the exposed right face 1d and the shield member 3 when the apparatus 100 is in the third configuration.

It will be appreciated by the skilled person that the shield member 3 can take a number of different shapes and forms in order to be suitable for the relevant apparatus, for example, flat plate, curved plate, irregular shape etc. The shield member can also be considered to comprise the backplate 4.

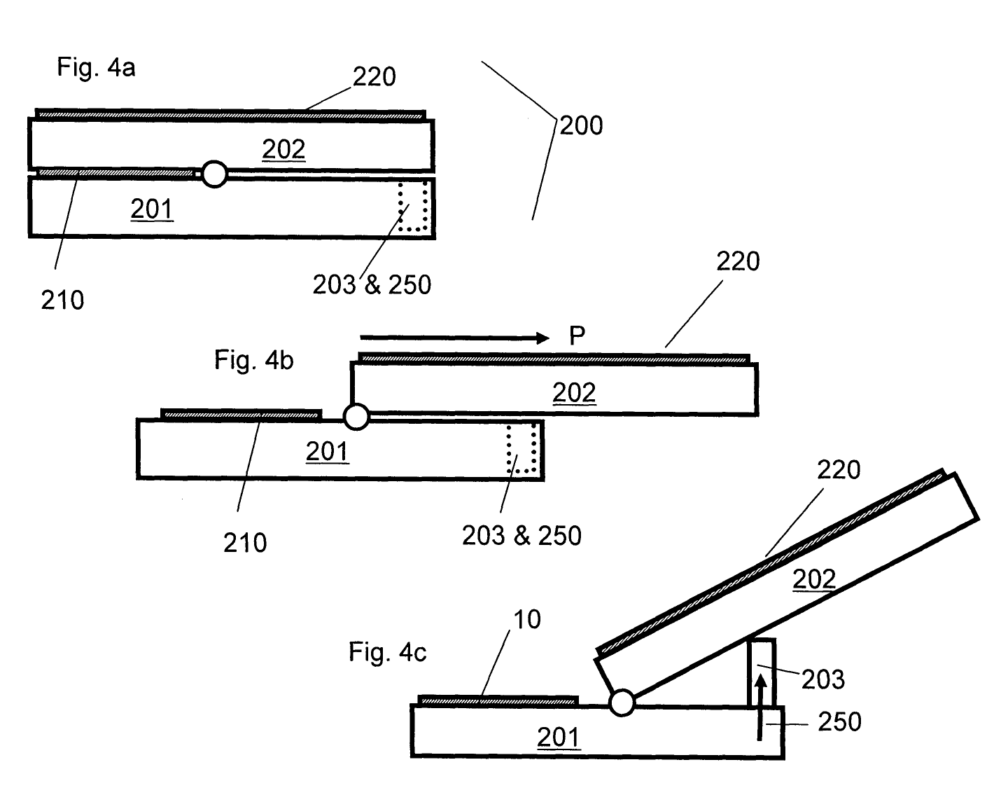

FIGS. 4a-4c show a further embodiment. The slide-tilt mechanism of the apparatus 200 functions in a similar way to the first embodiment.

In this embodiment, the shield member 203 is housed between the first and second housings 201, 202 in the non-shielding position.

The apparatus 200 further comprises a first biaser 250, the apparatus 200 being configured to use the biaser 250 to apply a force to the shield member 203 to push it out from between the first and second housings 201, 202 to the shielding position with/upon movement from the second configuration to the third configuration. That is, when the second housing 202 is tilted away from the first housing 201.

In this embodiment the biaser 250 is a helical spring mechanism (not shown). It will be appreciated by the skilled person that any mechanism that allows for movement of the shield member 203 from a non-shielding position into the shielding position will be suitable. For example, a mechanical bias, a gear mechanism, other types of spring mechanism, a resilient arrangement of the shield member 203, a combination of these, etc.

When the apparatus 200 is moved form the third configuration to the second configuration, the user pushes the second housing 202 against the biaser 250 so that it can be slid back to its non-shielding (stored) position in the first housing 201.

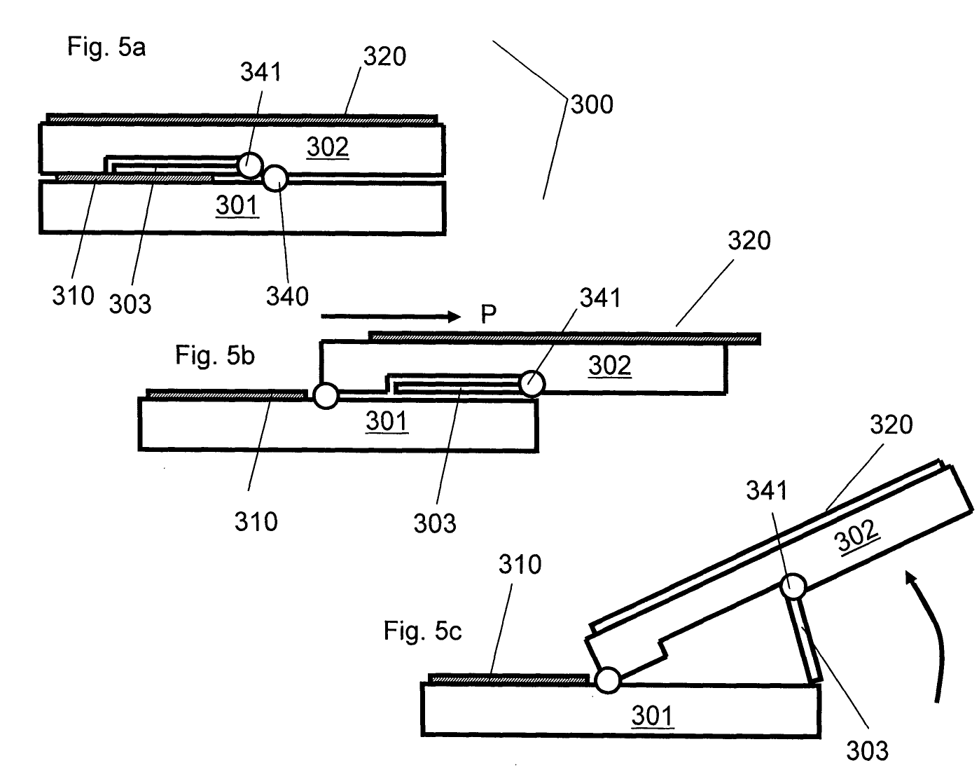

FIGS. 5a-5c show a further embodiment. The slide and tilt mechanism of apparatus 300 functions in a similar way as the first embodiment except for the following modifications.

In this embodiment, the shield member 303 is foldably housed between the first and second housings 301, 302 in the non-shielding position.

The second housing 302 further comprises a second pivot 341, the second pivot 341 being located/provided at the approximate midpoint of the bottom face 302b of the second housing 302 (see FIG. 5a).

The second pivot 341 connects one end of the shield member 303 to said midpoint of the bottom face 302b. This attachment allows the shield member to be slidably moved with the second housing 302 with movement between the first and second configurations. This pivotal attachment also allows the shield member 303 to be unfolded to provide the shielding position upon movement of the apparatus 300 from the second configuration to the third configuration.

This creates a ‘flip-up/flip-down’ arrangement for the shield member 303, by which the shield member 303 is likened to a ‘flap’ that is flush between the first and second housings 301, 302 in the first and second configurations, but can ‘flip-up’ into the shielding position upon movement of the apparatus 300 into the third configuration, and can ‘flip-down’ into the non-shielding position upon movement of the apparatus 300 into the second configuration.

In a further variation of this embodiment, the shield member 303 comprises a resilient material that allows it to be resiliently unfolded or “flipped down” with movement from the second configuration to the third configuration. The resilient material provides a biasing force to move the shield member 303 from the folded state (non-shielding position) to the unfolded state (shielding position) with said movement.

In another variation of embodiment, the second pivot 341 is instead provided on the vertex joining the top face 301a and the right face 301d of the first housing 301. The ‘flip-up/flip-down’ action here operates in reverse to the above described arrangement.

In a further variation of this embodiment, the first housing 301 comprises a latch that the shield member 303 latches into upon flipping down into the shielding position. The latch can be automatically or user releasable to allow the apparatus to be moved from the third configuration back to the second configuration. This can provide additional rigidity for the apparatus 300 when it is in the third configuration.

In a further variation, the free end of the shield member 303 is slidably connected to the sliding mechanism provided on the first housing 301. This allows the shield member 303 to slide into place as the apparatus 300 moves from the second configuration to the third configuration and can help to improve structural rigidity throughout movement of the apparatus 300 as the shield member 303 is connected to the apparatus at both ends.

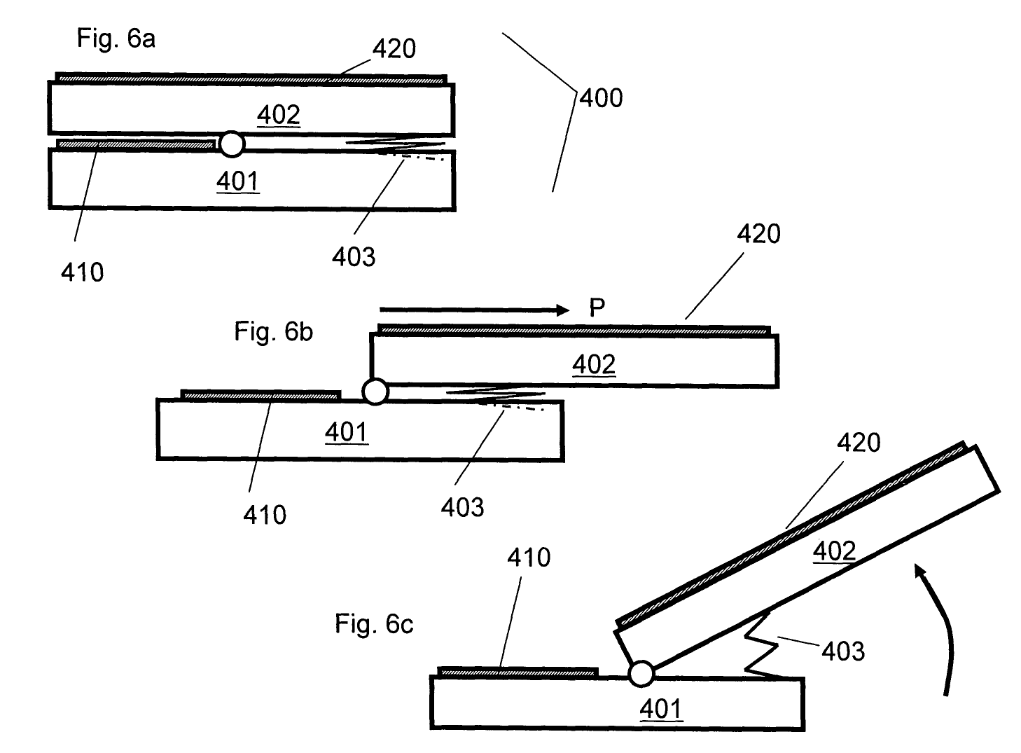

FIGS. 6a-6c show a further embodiment. The slide and tilt mechanism of apparatus 400 functions in substantially the same way as the first embodiment except for the following modifications.

In this embodiment, the shield member 403 is a concertina that is compressed between the first and second housings 401, 402 in the non-shielding position.

One end of the concertina is fixedly attached to the first housing 401 and the other end is slidably attached/connected to the second housing 402.

The shield member 403 is configured to expand from its compressed non-shielding position as shown in FIG. 6b into the shielding position as shown in FIG. 6c upon movement of the apparatus 400 from the second configuration to the third configuration.

In a further embodiment, the shield member 403 comprises a resilient material that allows it to be resiliently unfolded with movement from the second configuration to the third configuration. The resilient material provides a biasing force to move the shield member 403 from the compressed state (non-shielding position) to the uncompressed state (shielding position) with said movement.

In yet another embodiment, the shield member 403 is a flexible curtain that is configured to be unfurled/unrolled upon movement of the apparatus 400 from the second configuration to the third configuration. In one further embodiment the flexible curtain may be unfurled/unrolled by a roller bias mechanism that releases/retracts the curtain in substantially the same manner as a roller blind.

In each of these embodiments, the previously open defined spacing S between the covered portions 8 & 9 of the first and second housing 1 & 2 is partially enclosed or completely enclosed by a shield member. In some embodiments, this space can be used to contain or house certain components without risk, or with reduced risk of undesirable material penetrating the housing of the device. For example, in one embodiment, a camera lens is provided in the shield member 3 and the camera module (CCD and other components) are configured to be positioned in this spacing upon movement of the apparatus from the second configuration to the third configuration.

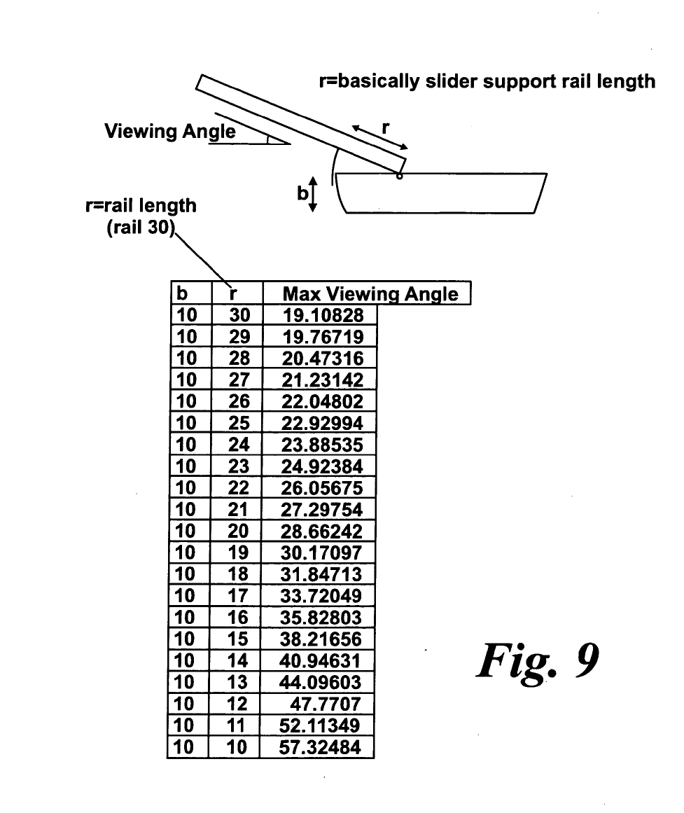

Referring to FIG. 9, there is a range of angles that can be set as maximum opening angle for the device. The angles can be selected so that when the device is in the tilted configuration (in other words, second housing is tilted relative to the first housing), the second housing still substantially overlies the first housing, or at least a portion of the first housing. This can help provide the device with added structural integrity, for example, because the point at which the tilting action occurs is not at an extreme edge but is located on the first face of the first housing.

The device can also be arranged (in certain example embodiments; not shown) to adopt a number of opening angles, in that the second housing can be moved from the untilted second configuration to a first tilted configuration at a first angle relative to the first housing, or further to a second tilted configuration at a second angle relative to the first housing. It will be appreciated by the skilled reader that any number of further discrete tilted configurations may be provided. It will also be appreciated that continuous tilting movement of the second housing relative to the first housing may be provided from the second configuration to a maximum opening angle in the third configuration, in that the second housing may adopt any tilted position inbetween the second configuration and third configuration.

In certain embodiments, the apparatus is configured to be mechanically biased to move the shield member, or even the apparatus itself between the various configurations, in that it is configured to move the apparatus from the first to the second configuration, from the second to the third configuration, and from the first to the second to the third configuration, or the shield member into the respective shielding or non-shielding position based on the detected configuration, and each in reverse. It will be appreciated by the skilled person that this function can be provided in a number of ways, for example by a motor (for example motorised bias), gear mechanisms (planetary, etc), resilient materials (for example leaf springs, coil springs), hydraulic mechanisms, a combination of these, or the like.

In further embodiments (not shown), the apparatus is also provided with a processor and movement sensors. The sensors are provided in the apparatus associated with the sliding arrangement to detect a relative position of first and second housing (in other words, whether the apparatus is in the first or second configuration), and to detect whether the second housing is in full sliding contact with the first housing (in other words, whether the second housing has been tilted relative to the first). The sensors are configured to detect movement between the different configurations and provide signals indicative of any such movement to the processor. The processor is configured to use these signals to change the state of operation of the device according to the configuration that the apparatus is detected to be in.

For example, when the apparatus is in the first configuration, the sensors detect this and communicate signals to the processor. The processor is configured to then move the apparatus into a state of operation most suited to that particular configuration (suitable for that form factor; for example typical mono-block phone operation with the input/output area providing for touch input and display output).

In further embodiments, the sensing/processing arrangement described above is used in combination with the mechanical biasing. The processor is further connected to the mechanical biasing. The processor is configured to, upon detection of an appropriate input, move the apparatus from one configuration to another by controlling the mechanical biasing. Suitable input can be user input provided via one of the input areas, or signals from the movement sensors indicating that the apparatus is starting to be moved from one configuration to another.

It will be apparent to the skilled person that this relative sliding movement can be configured (in further embodiments) to be in separate planes, and that these planes can be parallel or non-parallel planes.

It will be appreciated by the skilled person that the input/output area 20 may only perform one of these functions, in that the input/output area 20 may exclusively operate as an input or output area, or may operate as a combination of the two. There may also be provided a plurality of input or output areas on the faces of either housing.

It will be appreciated by the skilled reader that the apparatus/device/server and/or other features of particular apparatus/device/server may be provided by apparatus arranged such that they become configured to carry out the desired operations only when enabled, for example switched on, or the like. In such cases, they may not necessarily have the appropriate software loaded into the active memory in the non-enabled (for example switched off state) and only load the appropriate software in the enabled (for example on state). The apparatus may comprise hardware circuitry and/or firmware. The apparatus may comprise software loaded onto memory. Such software/computer programs may be recorded on the same memory/processor and/or on one or more memories/processors.

It will be appreciated that the aforementioned apparatus/circuitry/elements/processor may have other functions in addition to the mentioned functions, and that these functions may be performed by the same apparatus/circuitry/elements/processor. One or more disclosed aspects may encompass the electronic distribution of associated computer programs and computer programs (which may be source/transport encoded) recorded on an appropriate carrier (for example memory, signal).

With reference to any discussion of processor and memory (for example including ROM, CD-ROM etc), these may comprise a computer processor, Application Specific Integrated Circuit (ASIC), field-programmable gate array (FPGA), and/or other hardware components that have been programmed in such a way to carry out the inventive function.

The applicant hereby discloses in isolation each individual feature described herein and any combination of two or more such features, to the extent that such features or combinations are capable of being carried out based on the present specification as a whole, in the light of the common general knowledge of a person skilled in the art, irrespective of whether such features or combinations of features solve any problems disclosed herein, and without limitation to the scope of the claims. The applicant indicates that the disclosed aspects/embodiments may consist of any such individual feature or combination of features. In view of the foregoing description it will be evident to a person skilled in the art that various modifications may be made within the scope of the disclosure.

While there have been shown and described and pointed out fundamental novel features of the invention as applied to preferred embodiments thereof, it will be understood that various omissions and substitutions and changes in the form and details of the devices and methods described may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. Furthermore, in the claims means-plus-function clauses are intended to cover the structures described herein as performing the recited function and not only structural equivalents, but also equivalent structures. Thus although a nail and a screw may not be structural equivalents in that a nail employs a cylindrical surface to secure wooden parts together, whereas a screw employs a helical surface, in the environment of fastening wooden parts, a nail and a screw may be equivalent structures.

1-21. (canceled)

22. An apparatus, comprising a first housing, a second housing, and a shield member, the relative movements of which provide for a first, a second, and a third configuration for the apparatus, wherein:
the first and second housings are configured to be laterally slidable relative to one another between the first configuration and the second configuration, the second configuration providing a configuration in which the second housing is moved laterally away from the first housing compared to the first configuration, and the shield member is positioned in a non-shielding position to lie adjacent an exterior face of the first housing in the first and second configurations;
the apparatus is configured to be moveable from the second configuration to a third configuration in which the second housing is tilted relative to the first housing to reveal a defined spacing between the first housing and the tilted second housing; and
the apparatus is configured such that the shield member is moved to be positioned to a shielding position to at least partially enclose the spacing defined between the first housing and the tilted second housing in the third configuration with movement from the second configuration to the third configuration.

23. The apparatus according to claim 22, wherein the first and second housings are configured to be laterally moveable in the same plane between the first and second configurations.

24. The apparatus according to claim 22, wherein the apparatus is configured to be moveable from the second configuration to the third configuration about a pivot point such that relative lateral position of the first and second housings is substantially the same in the second and third configurations.

25. The apparatus according to claim 22, wherein the shield member is slidably attached to the second housing to allow the shield member to maintain its position with respect to the first and second housings in the first and second configurations but move with the second housing to the shielding position with movement from the second to the third configuration.

26. The apparatus according to claim 22, wherein the shield member comprises a non-flexible material.

27. The apparatus according to claim 22, wherein the shield member comprises a concertina, the shield member being compressed in the non-shielding position compared to the shielding position.

28. The apparatus according to claim 22, wherein the apparatus is configured such that the shield member covers an input/output port and/or camera lens and/or a memory card reader of the device in the non-shielding position.

29. The apparatus according to claim 22, wherein the apparatus is configured such that the shield member is provided along a major face of the defined spacing to substantially cover that major face.

30. The apparatus according to claim 22, wherein the shield member is configured to substantially completely enclose the defined spacing when in the third configuration.

31. The apparatus according to claim 22, wherein the shield member comprises a plurality of members to enclose the spacing defined between the first housing and the tilted second housing in the third configuration.

32. The apparatus according to claim 31, wherein the plurality of members are provided for respective faces of the spacing defined between the tilted first and second housings in the third configuration.

33. The apparatus according to claim 22, wherein the first and second housings are configured to be moved laterally in planes parallel to one another between the first and second configuration.

34. An apparatus according to claim 22, wherein the apparatus is a portable electronic device.

35. A computer-readable storage medium carrying one or more sequences of one or more instructions for one or more computer programs for an apparatus, the apparatus comprising a first housing, a second housing, and a shield member, relative movements of which provide for a first, a second, and a third configuration for the apparatus, wherein:
the first and second housings are configured to be laterally slidable relative to one another between the first configuration and the second configuration, the second configuration providing a configuration in which the second housing is moved laterally away from the first housing compared to the first configuration, and the shield member is positioned in a non-shielding position to lie adjacent an exterior face of the first housing in the first and second configurations;
the apparatus is configured to be moveable from the second configuration to a third configuration in which the second housing is tilted relative to the first housing to reveal a defined spacing between the first housing and the tilted second housing;
the apparatus is configured such that the shield member is moved to be positioned to a shielding position to at least partially enclose the spacing defined between the first housing and the tilted second housing in the third configuration with movement from the second configuration to the third configuration,
wherein when the one or more instructions are executed by one or more processors, the apparatus is caused to perform at least the following:
detect a current configuration of the apparatus; and
cause, at least in part, a movement of the shield member into position based, at least in part, on the detected current configuration.

36. A method of assembling an apparatus, the apparatus comprising a first housing, a second housing, and a shield member, relative movement of which provide for a first, a second, and a third configuration for the apparatus, wherein:
the first and second housings are configured to be laterally slidable relative to one another between the first configuration and the second configuration, the second configuration providing a configuration in which the second housing is moved laterally away from the first housing compared to the first configuration, and the shield member is positioned in a non-shielding position to lie adjacent an exterior face of the first housing in the first and second configurations;
the apparatus is configured to be moveable from the second configuration to a third configuration in which the second housing is tilted relative to the first housing to reveal a defined spacing between the first housing and the tilted second housing; and
the apparatus is configured such that the shield member is moved to be positioned to a shielding position to at least partially enclose the spacing defined between the first housing and the tilted second housing in the third configuration with movement from the second configuration to the third configuration,
wherein the method comprises assembling the first housing, the second housing, and the shield member for movement between the first, second and third configurations.
